(19) United States
(12) Patent Application Publication
(10) Pub. No.: US 2024/0306346 A1
(43) Pub. Date: Sep. 12, 2024

(54) BAFFLING ASSEMBLY FOR MITIGATING MOVEMENT OF A HEAT-TRANSFER LIQUID IN AN IMMERSION CASE

(71) Applicant: OVH, Roubaix (FR)

(72) Inventors: Ali CHEHADE, Moncheaux (FR); Mohamad HNAYNO, Roubaix (FR); Charbel MASRI, Lille (FR)

(21) Appl. No.: 18/588,720

(22) Filed: Feb. 27, 2024

(30) Foreign Application Priority Data
Mar. 9, 2023 (EP) 23305321.4

(51) Int. Cl. H05K 7/20

(52) U.S. Cl. CPC H05K 7/203; H05K 7/20327

(57) ABSTRACT

A baffling assembly for mitigating movement of a heat-transfer liquid in an immersion case and an immersion case assembly. The immersion case contains the heat-transfer liquid in which an electronic device is at least partially submerged. The baffling assembly includes at least one baffle element configured to be disposed proximate a top portion of the immersion case.

### CROSS REFERENCE

The present application claims priority to EP application Ser. No. 23/305,321.4, filed Mar. 9, 2023, entitled “BAFFLING ASSEMBLY FOR MITIGATING MOVEMENT OF A HEAT-TRANSFER LIQUID IN AN IMMERSION CASE”, the entirety of which is incorporated herein by reference.

### FIELD OF TECHNOLOGY

The present technology relates generally to cooling technologies, and more specifically to baffling assemblies for mitigating movement of a heat-transfer liquid in an immersion case.

### BACKGROUND

Electronic equipment, for example servers, memory banks, computer discs, and the like, is conventionally grouped in equipment racks. Large data centers and other large computing facilities may contain thousands of racks supporting thousands or even tens of thousands of servers.

The racks, including equipment mounted in their backplanes, consume large amounts of electric power and generate significant amounts of heat. Cooling needs are important in such racks. Some electronic devices, such as processors, generate so much heat that they could fail within seconds in case of a lack of cooling.

Immersion cooling (sometimes called immersive cooling) of equipment racks was recently introduced. Electronic components are inserted in an immersion case that is fully or partially filled with a heat-transfer liquid (sometimes called a non-conducting cooling liquid), for example an oil-based dielectric cooling liquid. Good thermal contact is obtained between the electronic components and the heat-transfer liquid. The immersion case may be open-ended on at least one side (e.g. a top side), and is generally filled with the heat-transfer liquid until the electronic components are completely submerged in the heat-transfer liquid.

Technicians or other personnel frequently need to rack equipment in and out, in order to replace defective components or perform other routine maintenance tasks requiring access to the electronic equipment. The act of racking equipment may cause motion of the heat-transfer liquid within the immersion case, leading to overflowing of the heat-transfer liquid and spillage outside of the immersion case. The loss of heat-transfer liquid may lead to the electronic equipment within the immersion case being inadequately covered by the remaining heat-transfer liquid and therefore degrading the overall heat transfer capability of the equipment rack. The spilled heat-transfer liquid also creates a safety hazard and needs to be cleaned, creating an additional maintenance burden for facility personnel. Facility operators may also face a substantial cost of replacing spilled heat-transfer liquid.

There is thus a desire to mitigate at least some of the aforementioned drawbacks.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on developers' appreciation of shortcomings associated with the prior art.

In particular, such shortcomings may comprise (1) overflowing of heat-transfer liquid when racking in or out electronic equipment; and/or (2) minimizing cleaning of spilled heat-transfer liquid.

In a first broad aspect of the present technology, there is provided a baffling assembly for mitigating movement of a heat-transfer liquid in an immersion case, the immersion case being configured to contain the heat-transfer liquid in which an electronic device is at least partially submerged. The baffling assembly includes at least one baffle element configured to be disposed proximate a top portion of the immersion case.

In some non-limiting implementations, the at least one baffle element is disposed at an open-ended top side of the immersion case.

In some non-limiting implementations, the at least one baffle element comprises a first baffle element and a second baffle element, the first baffle element extending along a first edge of the open-ended top side of the immersion case, the second baffle element extending along a second edge of the open-ended top side, opposed to the first edge of the open-ended top side of the immersion case.

In some non-limiting implementations, the first and second baffle elements have a curved planar shape, a first convex surface of the first baffle element and a second convex surface of the second baffle element are facing at least partially away from a surface of the heat-transfer liquid side of the immersion case, the first convex surface is disposed opposite to the second convex surface.

In some non-limiting implementations, the first and second baffle elements are staggered with respect to each other in a direction orthogonal to the first edge and the second edge.

In some non-limiting implementations, the first baffle element at least partially overhangs the second baffle element.

In some non-limiting implementations, the first and second baffle elements are disposed at least in part above the surface of the heat-transfer liquid.

In some non-limiting implementations, the at least one baffle element comprises a plurality of baffle elements.

In some non-limiting implementations, at least some of the plurality of baffle elements is movable in a direction parallel to the top portion of the immersion case.

In some non-limiting implementations, a distance between two consecutive baffle elements of the plurality of baffle element is constant.

In some non-limiting implementations, each of the baffle elements is a parallelogram-shaped plate member.

In some non-limiting implementations, each of the baffle elements is an oval-shaped plate member.

In some non-limiting implementations, each of the baffle elements defines at least one hole for letting the heat-transfer liquid flow therethrough.

In some non-limiting implementations, the plurality of baffle elements is at least partially immersed in the heat-transfer liquid.

In some non-limiting implementations, the at least one baffle element is mechanically attached to a board of the electronic device.

In some non-limiting implementations, the at least one baffle element is mechanically attached to the electronic device.

In some non-limiting implementations, each of the at least one baffle element defines one or more attachment points to secure the baffle element to the immersion case.

In a first broad aspect of the present technology, there is provided an immersion case assembly for hosting an electronic device. The immersion case assembly includes an immersion case configured to contain a heat-transfer liquid in which an electronic device is at least partially submerged and any one of the baffling assemblies disclosed herein.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is a schematic diagram of an immersion cooling system in accordance with a non-limiting implementation of the present technology;

FIG. 2 shows a perspective view of the cooling system of FIG. 1 in accordance with another non-limiting implementation of the present technology;

FIG. 3A shows a perspective view of the cooling system of FIG. 2 with a baffling assembly including a first baffle element and a second baffle element, in accordance with yet another non-limiting implementation of the present technology;

FIG. 3B shows a top elevation view of the cooling system of FIG. 3A;

FIG. 4A shows a perspective view of the cooling system of FIG. 2 with a baffling assembly including a plurality of baffle elements, in accordance with yet another non-limiting implementation of the present technology;

FIG. 4B shows a front elevation view of one of the plurality of baffle elements of FIG. 4A, in accordance with yet another non-limiting implementation of the present technology;

FIG. 5A shows a perspective view of the cooling system of FIG. 2 with a baffling assembly including a plurality of baffle elements, in accordance with yet another non-limiting implementation of the present technology; and

FIG. 5B shows a front elevation view of one of the plurality of baffle elements of FIG. 5A, in accordance with yet another non-limiting implementation of the present technology.

It should also be noted that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative systems embodying the principles of the present technology.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

With these fundamentals in place, we will now consider some non-limiting examples to illustrate various implementations of aspects of the present technology.

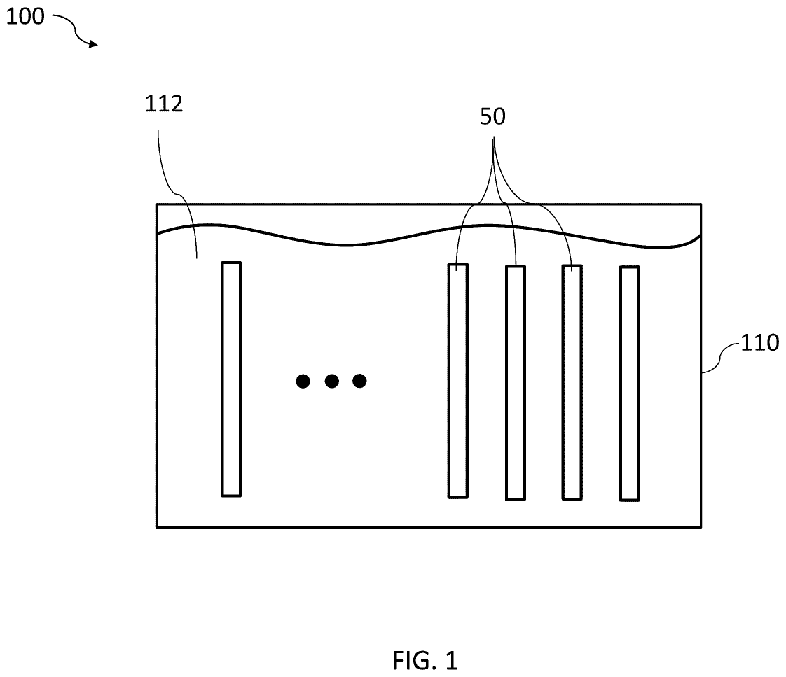

FIG. 1 is a schematic diagram of an immersion cooling system 100. In the shown implementation, the cooling system 100, comprises an immersion case 110 configured to receive a heat-transfer liquid 112 having a top surface 113 and to receive one or more electronic assemblies 50 immersed in the heat-transfer liquid 112. Each electronic assembly 50 may include at least one electronic component to be cooled. An electronic assembly 50 is described in greater details herein after. The heat-transfer liquid 112 may be, for example and without limitations, a dielectric cooling liquid.

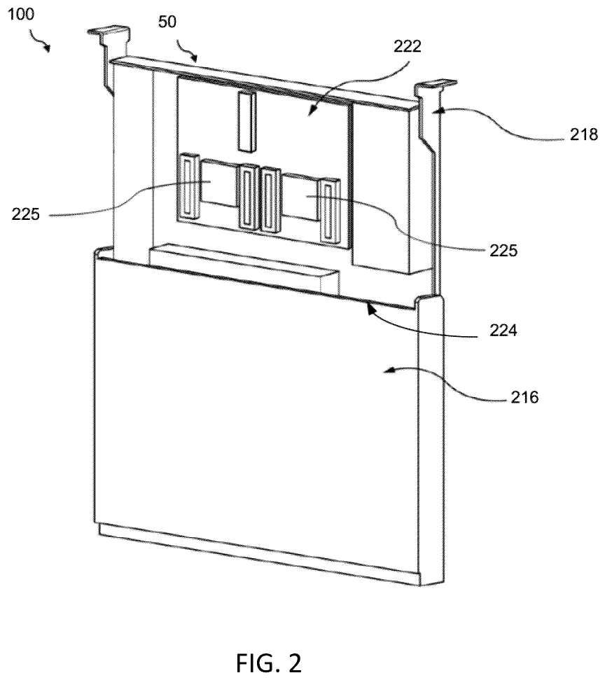

FIG. 2 shows a perspective view of a cooling system 100 in accordance with a non-limiting implementation of the present technology. As shown, the cooling system 100 includes a detachable frame, or “board” 218 of an electronic assembly 50, and an immersion case 216. The board 218 holds electronic components 222 of the electronic assembly 50 and may be immersed in the immersion case 216. The electronic components 222 of the electronic assembly 50 include one or more processors 225, among other components. Although the immersion case 216, board 218, and electronic components 222 are shown as separate parts, it will be understood by one of ordinary skill in the art that, in some embodiments, two or more of these components could be combined. For example, the electronic components 222 could be fixed directly on the board 218 and/or the immersion case 216.

It is contemplated that the electronic assemblies 50 may generate a significant amount of heat. Consequently, the immersion cooling system 100 provides cooling to the electronic assemblies 50 to prevent them from being damaged. As used herein, the immersion cooling system 100 is a cooling system in which the immersion case 216 is open such that the electronic assembly 50 is in direct contact with the first heat-transfer liquid 112, which either flows over at least portions of the electronic assembly 50, or in which at least portions of the electronic assembly 50 are submerged in the immersion case 216. Further, the board 218 including the electronic components 222 may be submerged at least in part in the immersion case 216. In this implementation, the board 218 may be inserted into the immersion case 216 via an open-ended top side 224 of the immersion case 216. FIG. 2 shows the board 218 in a partially inserted configuration into the immersion case 216. The open-ended top side 224 may remain at least partially open during operation of the electronic assembly 50, providing a non-scaled configuration for the immersion case 216. Such non-sealed configurations may be easier to manufacture and maintain than sealed configurations. Alternatively, the immersion case 216 may be closed and sealed once the board 218 in inserted, particularly if it is desired to operate the system 100 in a sealed configuration.

In some embodiments, the electronic assembly 50 may be a server that may be implemented as a conventional computer server. Each electronic assembly 50 may be implemented as a Dell™ PowerEdge™ Server running the Microsoft™ Windows Server™ operating system. Needless to say, each electronic assembly 50 may be implemented in any other suitable hardware, software, and/or firmware, or a combination thereof.

The electronic assembly 50 includes one or more electronic components 222 and the board 218 on which the one or more electronic assemblies 50 are mounted. The board 218 is at least in part immersed in the immersion case 216 that contains a volume of the heat-transfer liquid 112 for cooling of the electronic assembly 50.

In some embodiments, multiple electronic devices, similar to the electronic assembly 50, may be immersed in a single immersion case 216.

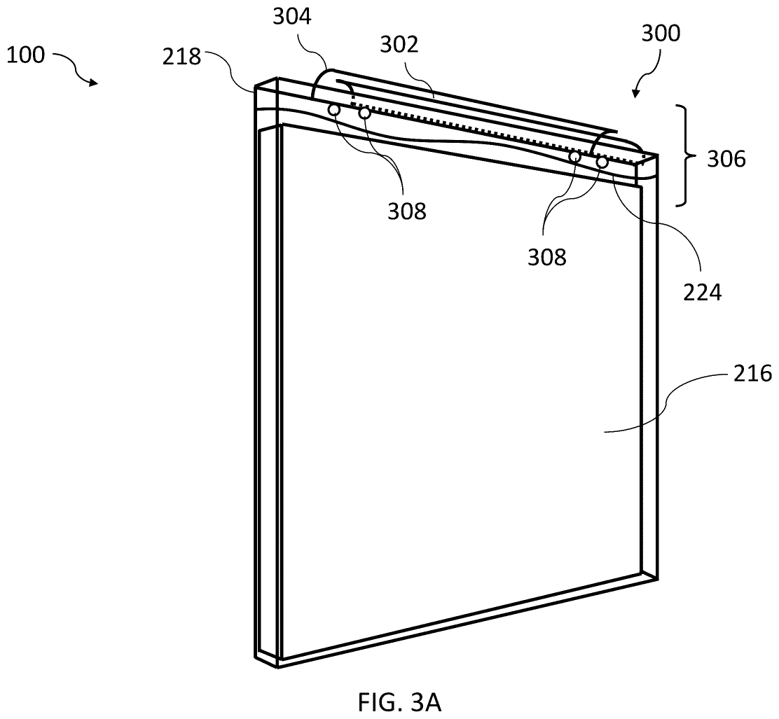

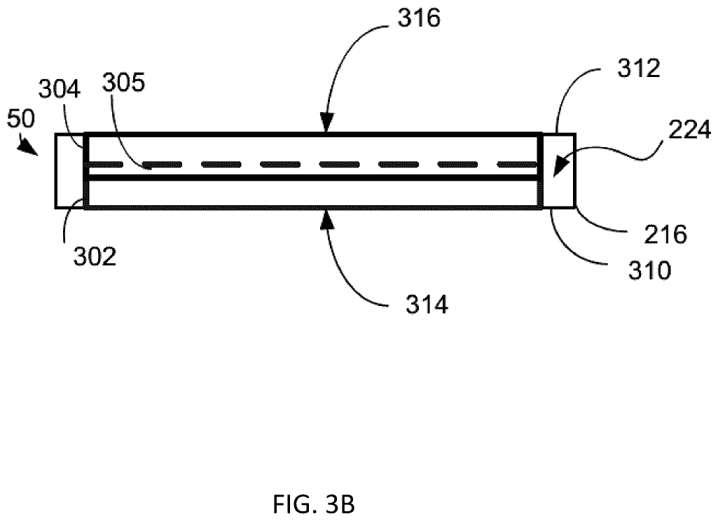

FIG. 3A shows a perspective view of the cooling system 100 of FIG. 2 in accordance with yet another non-limiting implementation of the present technology. FIG. 3B shows a top elevation view of the cooling system 100 of FIG. 3A. In FIG. 3A, the board 218 is shown in a fully inserted configuration into the immersion case 216. In other words, the board 218 is completely immersed in the immersion case 216 that contains a volume of the heat-transfer liquid 112 for cooling of the electronic assembly 50.

In the embodiment of FIG. 3A, the cooling system 100 is provided with a baffling assembly 300 for mitigating movement of the heat-transfer liquid 112 in the immersion case 216. Said movements may be for example caused by insertion and/or removal of the board 218 in the immersion case 216. In addition, the baffling assembly 300 may mitigate movements of the heat-transfer liquid 112 and their impact vibrations on a transport vehicle when the immersion case 216 is carried or transported. The baffling assembly 300 includes a first baffle element 302 and a second baffle element 304. The baffling assembly 300 is disposed proximate a top portion 306 of the immersion case 216. More specifically, the baffling assembly 300 is disposed at or near the open-ended top side 224 of the immersion case 216. The first baffle element 302 extends along a first edge 310 of the open-ended top side 224 of the immersion case 216 (see FIG. 3B), and the second baffle element 304 extends along a second edge 312 of the open-ended top side 224 of the immersion case 216, the second edge 312 opposed to the first edge 310. The first baffle element 302 and the second baffle element 304 are fixedly attached to a first wall 314 and to a second wall 316 of the immersion case 216, respectively, the first wall 314 opposite to the second wall 316 (see FIG. 3B), via attachment points 308, using, for example and without limitation, screws, nails, anchors, or adhesive. Each of the first baffle element 302 and the second baffle element 304 has a plurality of attachment points 308. It is contemplated that the baffling assembly 300 could also be detachably connected to the immersion case 216 using a clamping or mounting system (not shown) provided with the baffling assembly 300 and/or the immersion case 216. In some non-limiting implementations, the baffling assembly 300 may be attached to the immersion case 216 using fasteners (e.g. clips) attached to the board 218 or to the immersion case 216 itself. For example, the board 218 may define openings to accommodate the fasteners. In some implementations, the first baffle element 302 and the second baffle element 304 extend from the board 218.

As shown, the first baffle element 302 and the second baffle element 304 have a curved planar shape, where a first convex surface of the first baffle element 302 and a second convex surface of the second baffle element 304 are facing at least partially away from the top surface 113 of the heat-transfer liquid 112 of the immersion case 216, the first convex surface being disposed opposite to the second convex surface. The first baffle element 302 and the second baffle element 304 are staggered with respect to each other in a direction orthogonal to the top surface 113, i.e. the second baffle element 304 is elevated with respect to the first baffle element 302. It is contemplated that the first baffle element 302 may be elevated with respect to the second baffle element 304 instead. In the embodiment shown, the second baffle element 304 at least partially overhangs the first baffle element 302. However, it is contemplated that the first baffle element 302 could at least partially overhang the second baffle element 304 instead. Moreover, the first baffle element 302 and the second baffle element 304 are disposed at least in part above the surface of the heat-transfer liquid 112. In some implementations, the first baffle element 302 and the second baffle element 304 have a curved planar shape defining holes.

In some embodiments, the baffling assembly 300 may have a single baffle element, or more than two baffle elements, as described hereinafter. The baffle elements may be disposed at different positions relative to the immersion case 216, for instance near, proximate, or just under the first edge 310 and/or the second edge 312. The baffle elements may have various shapes and orientations with respect to each other, as will be apparent to the person skilled in the art having the benefit of the present disclosure. For example, the first baffle element 302 and the second baffle element 304 may extend along an entirety, or along a portion thereof, of the edges of the immersion case 216.

As shown on FIG. 3B, an overlap area 305 may be created by the overhang of the second baffle element 304 relative to the first baffle element 302. It is contemplated that the first baffle element 302 and the second baffle element 304 may be positioned such that there is no overlap area 305.

In some implementations, the baffling assembly 300 further include a third and a fourth baffle elements extending along a third and fourth edges of the immersion case 216 (i.e. extending along a width of the immersion case 216).

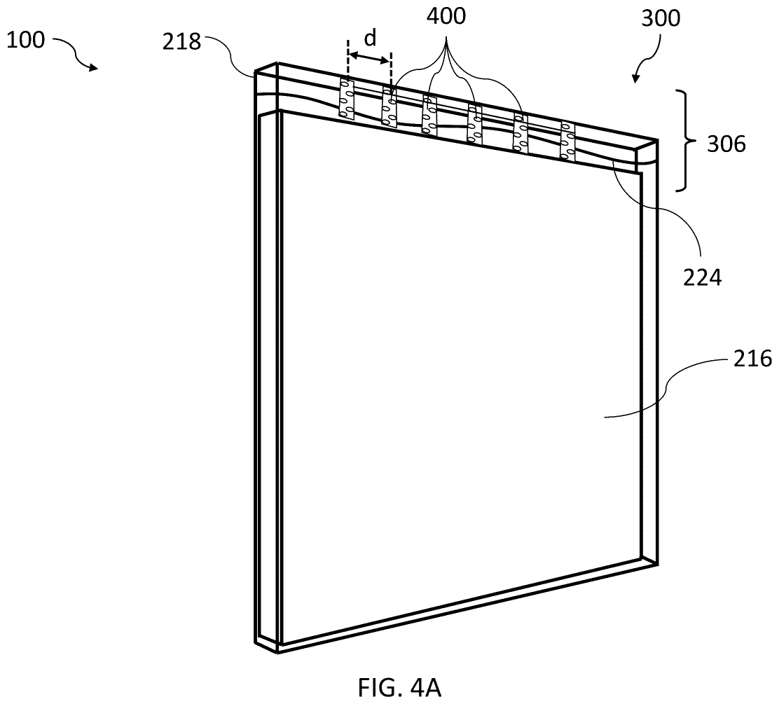

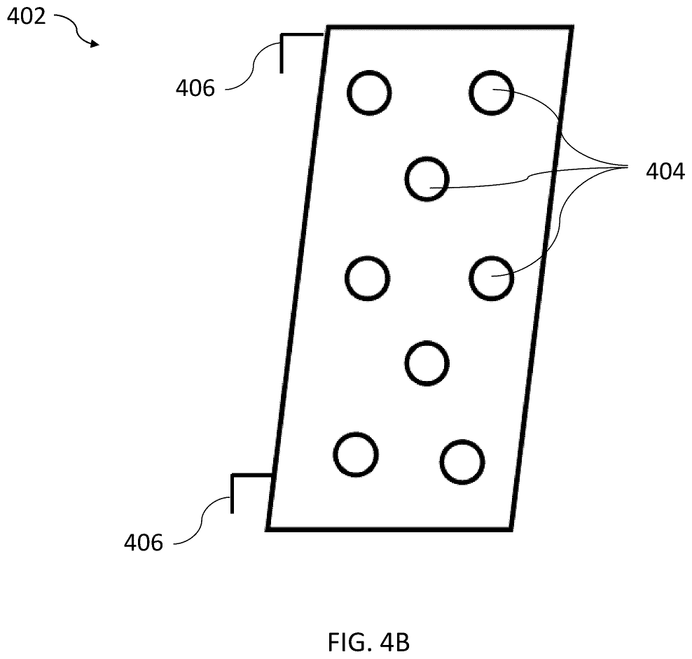

FIG. 4A shows a perspective view of the cooling system 100 of FIG. 2 in accordance with yet another non-limiting implementation of the present technology. In FIG. 4A, similarly to FIG. 3A, the board 218 is shown in a fully inserted configuration into the immersion case 216.

In the embodiment shown in FIG. 4A, the baffling assembly 300 includes a plurality of baffle elements 400 disposed in a linear array parallel to the first edge 310 and to the second edge 312 of the immersion case 216 (see FIG. 3B). At least some of the plurality of baffle elements 400 may be movable in a direction parallel to the first edge 310 and the second edge 312. Alternatively, a distance d between two consecutive baffle elements of the plurality of baffle elements 400 may be constant. In some non-limiting implementations, the baffling elements 400 may be attached to the immersion case 216 using fasteners (e.g. clips) attached to the board 218. For example, the board 218 may define openings to accommodate the fasteners.

FIG. 4B shows a front elevation view of one of the plurality of baffle elements 400 of FIG. 4A in accordance with yet another non-limiting implementation of the present technology. Each of the baffle elements 400 as illustrated is a parallelogram-shaped plate member 402. The plate member 402 defines a plurality of holes 404 for letting at least some of the heat-transfer liquid 112 flow therethrough. It is contemplated that the plate member 402 could define no holes or a different number of holes 404. The baffle elements 400 include attachment points 406 that may include, for example and without limitation, screws, nails, anchors, or adhesive to secure the baffle elements to the immersion case 216.

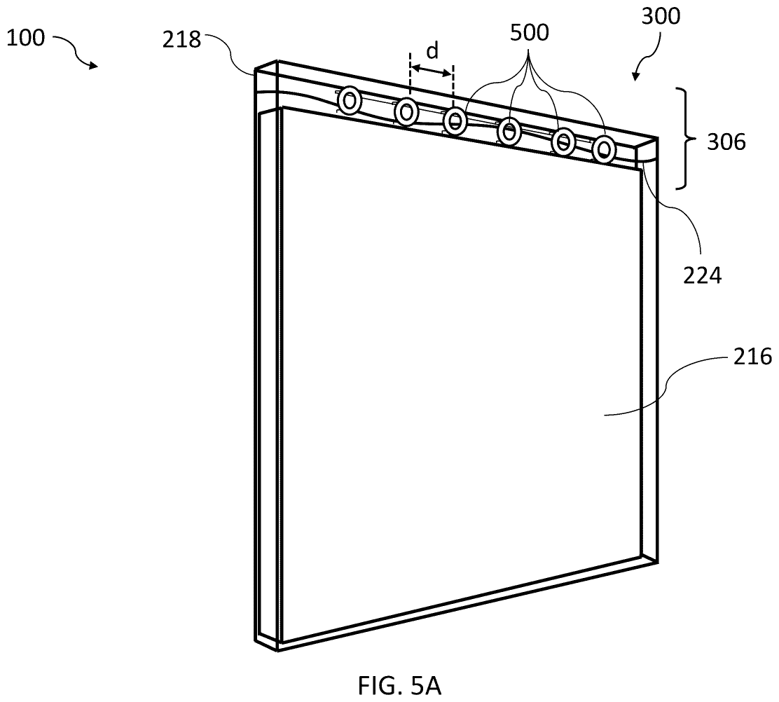

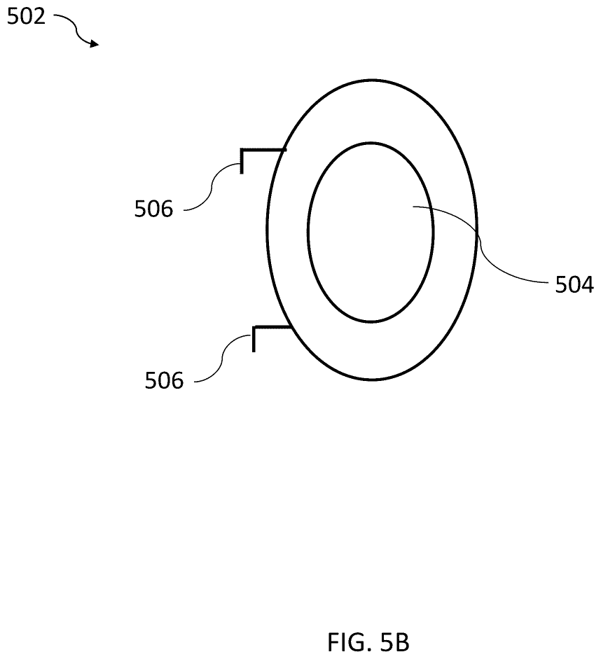

FIG. 5A shows a perspective view of the cooling system 100 of FIG. 2 in accordance with yet another non-limiting implementation of the present technology. In FIG. 5A, similarly to FIGS. 3A and 4A, the board 218 is shown in a fully inserted configuration into the immersion case 216.

In the embodiment shown in FIG. 5A, similarly to FIG. 4A, the baffling assembly 300 includes a plurality of baffle elements 500 disposed in a linear array parallel to the first edge 310 and to the second edge 312 of the immersion case 216. At least some of the plurality of baffle elements 500 may be movable in a direction parallel to the first edge 310 and to the second edge 312. Alternatively, the distance d between two consecutive baffle elements of the plurality of baffle elements 500 may be constant.

FIG. 5B shows a front elevation view of one of the plurality of baffle elements 500 of FIG. 5A in accordance with yet another non-limiting implementation of the present technology. Each of the baffle elements 500 as illustrated is an oval-shaped plate member 502. The plate member 502 defines at least one hole 504 for letting at least some of the heat-transfer liquid 112 flow therethrough. It is contemplated that the plate member 502 could define no holes or a different number of holes 504. The baffle elements 500 include attachment points 506 that may include, for example and without limitation, screws, nails, anchors, or adhesive to secure the baffle elements to the immersion case 216.

It is contemplated that other geometries of the baffling assembly 300 could be used. Each of the plurality of baffle elements 400 or 500 could have a shape other than a parallelogram or an oval, for example a triangular, hexagonal, or any other suitable polygonal shape. The plurality of baffle elements 400 or 500 could be disposed in a staggered configuration, with odd baffle elements staggered with respect to even baffle elements (or vice versa) in a direction substantially parallel to the open-ended top side 224 of the immersion case 216. The plurality of baffle elements 400 or 500 may be provided in a fixed configuration or may alternatively be movable. Finally, in some embodiments, the distance d between two consecutive baffle elements of the plurality of baffle elements 400 or 500 may be variable. In some non-limiting implementations, the baffling elements 500 may be attached to the immersion case 216 using fasteners (e.g. clips) attached to the board 218. For example, the board 218 may define openings to accommodate the fasteners.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

It should be expressly understood that not all technical effects mentioned herein need to be enjoyed in each and every embodiment of the present technology.

As such, the immersion cooling system implemented in accordance with some non-limiting embodiments of the present technology can be represented as follows, presented in numbered clauses.

### CLAUSES

[Clause 1] A baffling assembly for mitigating movement of a heat-transfer liquid in an immersion case, the immersion case being configured to contain the heat-transfer liquid in which an electronic device is at least partially submerged, the baffling assembly comprising:
at least one baffle element configured to be disposed proximate a top portion of the immersion case.

[Clause 2] The baffling assembly of clause 1, wherein the at least one baffle element is disposed at an open-ended top side of the immersion case.

[Clause 3] The baffling assembly of clause 2, wherein the at least one baffle element comprises a first baffle element and a second baffle element,
the first baffle element extending along a first edge of the open-ended top side of the immersion case,
the second baffle element extending along a second edge of the open-ended top side, opposed to the first edge of the open-ended top side of the immersion case.

[Clause 4] The baffling assembly of clause 3, wherein
the first and second baffle elements have a curved planar shape,
a first convex surface of the first baffle element and a second convex surface of the second baffle element are facing at least partially away from a surface of the heat-transfer liquid side of the immersion case,
the first convex surface is disposed opposite to the second convex surface.

[Clause 5] The baffling assembly of clause 4, wherein the first and second baffle elements are staggered with respect to each other in a direction orthogonal to the first edge and the second edge.

[Clause 6] The baffling assembly of clause 5, wherein the first baffle element at least partially overhangs the second baffle element.

[Clause 7] The baffling assembly of clause 4, wherein the first and second baffle elements are disposed at least in part above the surface of the heat-transfer liquid.

[Clause 8] The baffling assembly of clause 1 or 2, wherein the at least one baffle element comprises a plurality of baffle elements.

[Clause 9] The baffling assembly of clause 8, wherein at least some of the plurality of baffle elements is movable in a direction parallel to the top portion of the immersion case.

[Clause 10] The baffling assembly of clause 8 or 9, wherein a distance between two consecutive baffle elements of the plurality of baffle element is constant.

[Clause 11] The baffling assembly of any one of clauses 8 to 10, wherein each of the baffle elements is a parallelogram-shaped plate member.

[Clause 12] The baffling assembly of any one of clauses 8 to 10, wherein each of the baffle elements is an oval-shaped plate member.

[Clause 13] The baffling assembly of any one of clauses 8 to 12, wherein each of the baffle elements defines at least one hole for letting the heat-transfer liquid flow therethrough.

[Clause 14] The baffling assembly of any one of clauses 8 to 13, wherein the plurality of baffle elements is at least partially immersed in the heat-transfer liquid.

[Clause 15] The baffling assembly of any one of clauses 1 to 14, wherein the at least one baffle element is mechanically attached to a board of the electronic device.

[Clause 16] The baffling assembly of any one of clauses 1 to 14, wherein the at least one baffle element is mechanically attached to the electronic device.

[Clause 17] The baffling assembly of any one of clauses 1 to 16, wherein each of the at least one baffle element defines one or more attachment points to secure the baffle element to the immersion case.

[Clause 18] An immersion case assembly for hosting an electronic device, the immersion case assembly comprising:
an immersion case configured to contain a heat-transfer liquid in which an electronic device is at least partially submerged; and
the baffling assembly of any one of clauses 1 to 17.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A baffling assembly for mitigating movement of a heat-transfer liquid in an immersion case, the immersion case being configured to contain the heat-transfer liquid in which an electronic device is at least partially submerged, the baffling assembly comprising:
at least one baffle element configured to be disposed proximate a top portion of the immersion case.

2. The baffling assembly of claim 1, wherein the at least one baffle element is disposed at an open-ended top side of the immersion case.

3. The baffling assembly of claim 2, wherein the at least one baffle element comprises a first baffle element and a second baffle element,
the first baffle element extending along a first edge of the open-ended top side of the immersion case,
the second baffle element extending along a second edge of the open-ended top side, opposed to the first edge of the open-ended top side of the immersion case.

4. The baffling assembly of claim 3, wherein
the first and second baffle elements have a curved planar shape,
a first convex surface of the first baffle element and a second convex surface of the second baffle element are facing at least partially away from a surface of the heat-transfer liquid side of the immersion case,
the first convex surface is disposed opposite to the second convex surface.

5. The baffling assembly of claim 4, wherein the first and second baffle elements are staggered with respect to each other in a direction orthogonal to the first edge and the second edge.

6. The baffling assembly of claim 5, wherein the first baffle element at least partially overhangs the second baffle element.

7. The baffling assembly of claim 4, wherein the first and second baffle elements are disposed at least in part above the surface of the heat-transfer liquid.

8. The baffling assembly of claim 1, wherein the at least one baffle element comprises a plurality of baffle elements.

9. The baffling assembly of claim 8, wherein at least some of the plurality of baffle elements is movable in a direction parallel to the top portion of the immersion case.

10. The baffling assembly of claim 8, wherein a distance between two consecutive baffle elements of the plurality of baffle element is constant.

11. The baffling assembly of claim 8, wherein each of the baffle elements is a parallelogram-shaped plate member.

12. The baffling assembly of claim 8, wherein each of the baffle elements defines at least one hole for letting the heat-transfer liquid flow therethrough.

13. The baffling assembly of claim 1, wherein the at least one baffle element is mechanically attached to a board of the electronic device.

14. The baffling assembly of claim 1, wherein the at least one baffle element is mechanically attached to the electronic device.

15. An immersion case assembly for hosting an electronic device, the immersion case assembly comprising:
an immersion case configured to contain a heat-transfer liquid in which an electronic device is at least partially submerged; and
the baffling assembly of claim 1.

16. The baffling assembly of claim 2, wherein the at least one baffle element comprises a first baffle element and a second baffle element,
the first baffle element extending longitudinally along an edge of the open-ended top side of the IC,
the second baffle element extending longitudinally parallel to the first baffle element.

17. The baffling assembly of claim 16, wherein the first and second baffle elements overlap each other.

18. The baffling assembly of claim 16, wherein at least one of the first and second baffles has a curved shape.

19. The baffling assembly of claim 18, wherein a lateral section of at least one of the first and second baffles has a circular arc shape.
